(19) United States
(12) Patent Application Publication
(10) Pub. No.: US 2005/0189535 A1
(43) Pub. Date: Sep. 1, 2005

(54) Organic light-emitting device and method of fabricating the same

(75) Inventors: Wei-Chieh Hsueh, Tainan City (TW); Yaw-Ming Tsai, Taichung Hsien (TW)

Correspondence Address: LIU & LIU, 444 S. FLOWER STREET, SUITE 1750, LOS ANGELES, CA, 90071, US

(73) Assignee: Toppoly Optoelectronics Corp.

(21) Appl. No.: 10/971,446

(22) Filed: Oct. 21, 2004

(30) Foreign Application Priority Data
Feb. 26, 2004 (TW) 93104900

(51) Int. Cl. H01L 35/24

(52) U.S. Cl. 257/40

(57) ABSTRACT

An organic light-emitting device and method of fabricating the same. A substrate is provided. A first electrode is formed on the substrate. A light-emitting layer is disposed on the first electrode, and a second electrode is disposed on the light-emitting layer, wherein the first and second electrodes define a pixel area corresponding to an active light emitting area of the light-emitting layer. A light-shielding pattern is defined around the active light emitting area, to block stray light emitted by the light emitting-layer outside the active light emitting area.

### BACKGROUND OF THE INVENTION

1. Field of the Invention

The present invention relates to an organic light-emitting device, and more particularly to an organic light-emitting device with a light-shielding layer and method of fabrication the same.

2. Description of the Related Art

With recent development, organic light-emitting devices (OLEDs) have become a potential candidate to replace Liquid Crystal Displays (LCDs) for next-generation display. With their active light-emitting characteristics, OLEDs, unlike LCDS, do not require a backlight module to provide a light source, benefiting weight reduction. In addition, OLEDs have many distinguished advantages such as high contrast, fast response rate, high brightness, and wider viewing angle. The organic light-emitting diode uses an organic layer as an active layer, sandwiched between an anode and cathode electrodes to form a stacked layer. OLEDs are divided into small molecule and polymer device types according to the materials of their active layers.

FIG. 1 is a cross-section of a conventional OLED. The OLED 100 includes a transparent substrate 10, a transparent indium tin oxide (ITO) layer 20 as an anode electrode, a silicon oxide pattern 40 to define pixel areas, an organic insulating layer 50, a layer of polyethylenedioxy thiophene (PEDOT) 60 to serve as a buffer layer, a organic light-emitting layer 80, and a cathode electrode 90 of metals or alloys (such as Ca, Al, MgAg or AlLi).

By applying an appropriate potential difference between the anode electrode 20 and the cathode electrode 90, the organic light-emitting layer 80 emits a light 30 of a predetermined wavelength, penetrating the anode electrode 20 and the transparent substrate 10, in an active light emitting area.

The buffer layer 60 adjusts the energy level between the anode electrode 20 and the organic light-emitting layer 80, thereby enhancing the hole-injecting efficiency and lowering operation voltage. The buffer layer 60 is generally made of low-resistance materials, for example, PEDOT, a kind of conductive polymer. Thus, when the current flows along the direction shown by the arrow in FIG. 1 during operation, the area of the polymer light-emitting layer 80 passed by the current is electrically excited and thereby emits a stray light 30′ of a predetermined wavelength. Because the silicon oxide pattern 40 is pervious to light, the emitted light 30′ thereby penetrates through the silicon oxide pattern 40 and the transparent substrate 10, resulting in light-leakage and a larger light-emitting area than predetermined, deteriorating display performance.

### SUMMARY OF THE INVENTION

The present invention provides an organic light-emitting device and method of fabricating the same to ameliorate light leakage in non-pixel areas and improve display performance without significantly complicating the fabrication process or increasing the number of lithography steps.

According to one aspect of the present invention, a light-shielding pattern is disposed to define the pixel areas, and block light possibly penetrating from the non-pixel areas, wherein the light-shielding pattern can be an opaque pattern of metals, insulators or organic materials. In the embodiment of an OLED device, the light-shielding pattern is positioned outside the active light emitting region defined by the electrode (e.g., the anode), where stray light may be emitted.

In another aspect of the present invention, the light shielding layer is provided with another layer in the fabrication process. According to one embodiment, the present invention provides a fabrication method for an organic light-emitting device, comprising providing a substrate, forming a driving matrix on the substrate, forming a light-shielding pattern on the substrate to define a plurality of pixel areas within the driving matrix, forming a first electrode on the pixel area, forming an organic light-emitting layer on the first electrode, and forming a second electrode on the organic light-emitting layer.

In another embodiment, the present invention further provides an organic light-emitting device, comprising a substrate, a driving matrix on the substrate, a light-shielding pattern on the substrate, defining a plurality of pixel areas within the driving matrix, a first electrode on the pixel area, an organic light-emitting layer on the first electrode, and a second electrode on the organic light-emitting layer.

### DESCRIPTION OF THE DRAWINGS

The present invention can be more fully understood by reading the subsequent detailed description and examples with references made to the accompanying drawings, wherein:

FIG. 1 is a cross-section of a conventional OLED;

FIG. 2 is a schematic plan view illustrating an OLED device of active matrix drive type according to one embodiment of the present invention;

FIGS. 3A-3E illustrate fabrication of an OLED device of active matrix drive type according to one embodiment of the present invention;

FIG. 4 is a schematic diagram illustrating an OLED display device of the present invention; and

FIG. 5 is a schematic diagram illustrating an electronic device, incorporating the OLED display device of the present invention.

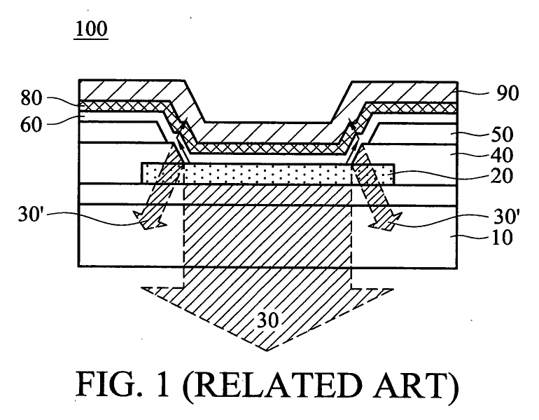

### DETAILED DESCRIPTION OF THE INVENTION

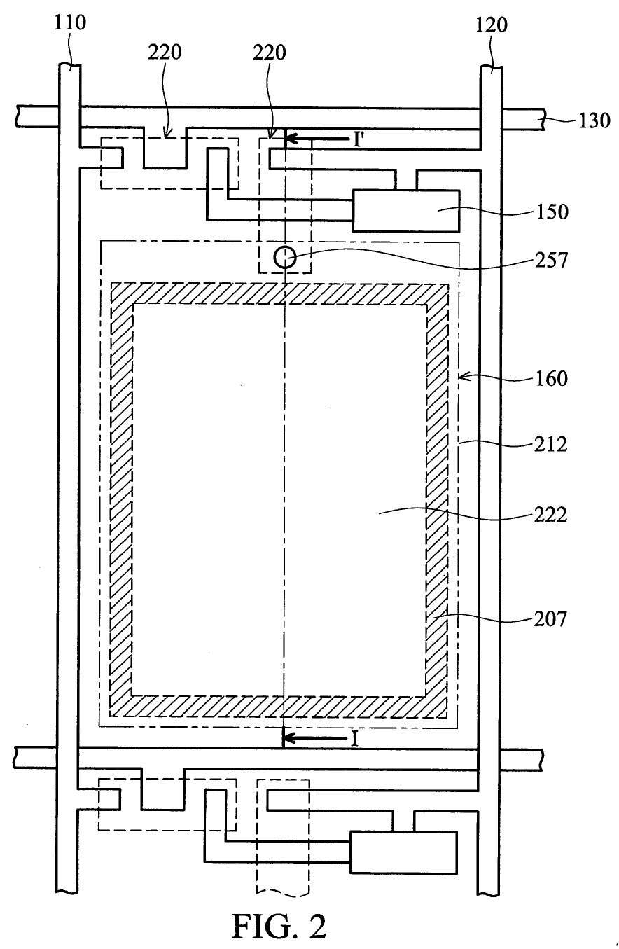

FIG. 2 is a schematic plan view illustrating an OLED device of active matrix drive type according to an embodiment of the present invention.

The driving matrix of the present invention may be an a-Si (amorphous silicon) TFTs array or an LTPS (low temperature polysilicon) TFTs array disposed on a transparent substrate of, for example, glass substrate.

In one embodiment, a driving matrix substrate of an LTPS array, with top-gate TFTs, is used to illustrate the inventive OLED and the method of fabricating the same. However, a driving matrix substrate with bottom-gate TFTs is also applicable.

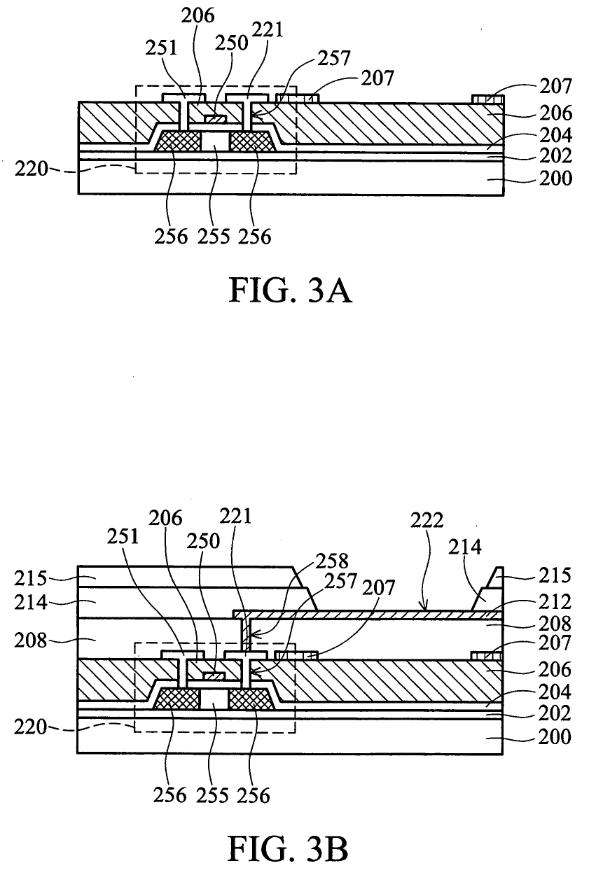

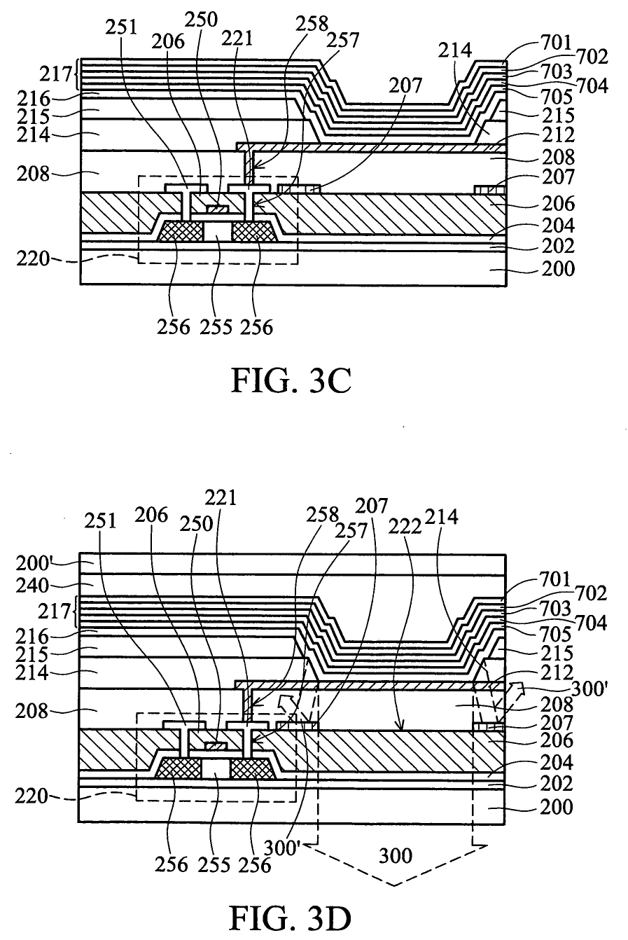

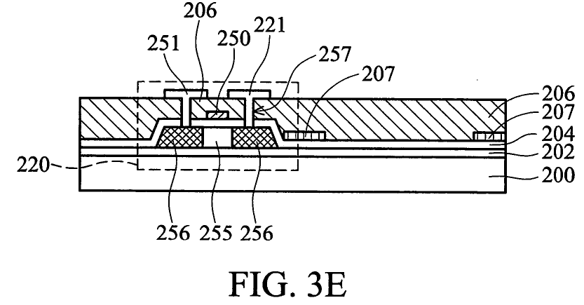

An OLED device of active matrix drive type according to this embodiment has at least one thin film transistor 220 and an organic LED device 160 provided on a substrate 200 for each pixel as shown in FIGS. 2 and 3D. FIG. 3D is a cross section of FIG. 2 taken along the line I-I′ in the direction indicated by the arrow.

The OLED device 160 includes a pixel electrode 212, an organic light emitting layer 217 on the pixel electrode 212, and a counter electrode 240 provided on the organic light emitting layer 217.

A planarization film 208 is provided over the thin film transistor 220 on the substrate 200, and the OLED device 160 is provided on the planarization film 208.

A source electrode 251 is provided on a source region 256 of the thin film transistor 220.

A metal light-shielding pattern 207 is formed on the dielectric layer 206, disposed around a predetermined pixel area 222 (predetermined area 222 of an organic light-emitting layer). While metal light-shielding pattern 207 is shown in FIG. 3D to be a structure separate from drain electrode 221, the pattern 207 may be connected to the drain electrode 221, or other components in the structure shown.

The metal light-shielding pattern 207 defines the predetermined pixel area 222, and also blocks light possibly penetrating through the first substrate 200 from the non-pixel areas.

In FIG. 2, reference numeral 130 denote scanning line, and reference numerals 110, 120, 220 and 150 denote a signal line, a common line, thin film transistor and a capacitor, respectively.

FIGS. 3A-3E are used, with the embodiment, to explain the inventive OLED and the method of fabricating the same.

In FIG. 3A, a first substrate 200 is provided with a buffer layer 202 thereon. A plurality of top-gate LTPS-TFTs 220 are formed on the buffer layer 202, wherein the top-gate LTPS-TFT 220 comprises a gate electrode 250, a source electrode 251, a drain electrode 221, a gate insulating layer 204, a channel region 255, and a source/drain region 256. The drain electrode 221 couples to the source/drain region 256 via a contact hole 257 of a dielectric layer 206. The top-gate LTPS-TFT 220 is fabricated by forming a poly-Si layer on the buffer layer 202, defining the poly-Si layer into the source/drain region 256 and the channel region 255, forming the gate insulating layer 204 on the poly-Si layer, forming a conductive layer (not shown) on the gate insulating layer 204, defining the conductive layer by photolithography to form the gate electrode 250 above the channel region 255, forming the dielectric layer 206 on the first substrate 200, defining the dielectric layer 206 to form contact holes and expose the source/drain region 256, conformally forming a source/drain electrode layer (not shown) on the first substrate 200, and defining the electrode layer to form the source electrode 251 and drain electrode 221 by photolithography.

Meanwhile, during formation of the source electrode 251 and drain electrode 221, a metal light-shielding pattern 207, is formed on the dielectric layer 206, disposed around a predetermined pixel area 222. While metal light-shielding pattern 207 is shown in FIG. 3B to be a structure separate from drain electrode 221, the pattern 207 may be connected to the drain electrode 221, or other components in the structure shown.

The light-shielding pattern 207 is simultaneously formed by photolithography, together with the source electrode 251 and drain electrode 221, as separate or connected structure. According to the invention, the light-shielding pattern 207 may also be simultaneously formed by photolithography, together with the gate electrode 250, as shown in FIG. 3E. Therefore, the invention may be performed without complicating fabrication or increasing the number of photolithography steps. Furthermore, the materials of the light-shielding pattern 207 are not limited to metals, and many materials, including insulators and organic materials, with light-shielding properties, are applicable.

The first substrate 200 is a transparent substrate of, for example, glass or polymer. As a polymeric substrate, the first substrate 200 is a substrate of polyethyleneterephthalates, polyesters, polycarbonates, polyacrylates or polystyrenes. The LTPS-TFTs 220 serve as controlling units of the OLED.

In FIG. 3B, a dielectric layer 208 with a contact hole 258 corresponding to the drain electrode 221 is formed on the first substrate 200. A first electrode 212 is then conformally formed on the dielectric layer 208, coupling to the drain electrode 221 and covering the pixel area 222 defined by the light-shielding pattern 207. The first electrode 212 may be a layer of indium tin oxide (ITO), indium zinc oxide (IZO), aluminum zinc oxide (AZO) or zinc oxide (ZnO), formed by sputtering, electron-beam evaporation deposition, thermal evaporation deposition, chemical vapor deposition or spray pyrolysis.

Then, a first insulating layer 214 is formed on the first electrode 212, then a second insulating layer 215 is formed on the first insulating layer 214. The first insulating layer 214 may be a silicon oxide layer; the second insulating layer 215 may be a polyimide layer. The first, second insulating layers 214, 215 are then etched, using the first electrode 212 as an etchstop, to define a predetermined area 222 for an organic light-emitting layer 217 (as shown in FIG. 3C) on the first electrode 212.

Next, in FIG. 3C, a buffer layer 216 of, for example, PEDOT is formed on the first substrate 200, covering the pixel area 222 to adjust the energy level between the first electrode 212 and the organic light-emitting layer 217.

The organic light-emitting layer 217 is then formed on the buffer layer 216. The organic light-emitting layer 217 comprises polymer light-emitting materials, formed by spin-coating, ink-jet or printing.

In the embodiment, the organic light-emitting layer 217 comprises an electron-injecting layer 701, an electron transport layer 702, a light emitting layer 703, a hole transport layer 704 and a hole-injecting layer 705. The organic light-emitting layer 217 can be small molecule organic light-emitting material formed by vacuum deposition.

In FIG. 3D, a second electrode 240 is formed on the organic light-emitting layer 217 serving as a cathode of the OLED. The second electrode 240 may be formed by vacuum thermal evaporation deposition or sputtering. To serve as the cathode of an OLED, materials are preferable, such as Ca, Al, Mg, MgAg, AlLi, in which Mg, MgAg, or a stack of Mg, MgAg and ITO are more preferable.

Finally, a second substrate 200′ is disposed on the cathode electrode 240. The fabrication of the OLED is thereby complete.

Accordingly, by disposing the light-shielding pattern 207, the pixel area 222 (or active light-emitting area) is defined, allowing light 300 emitted from the organic light-emitting layer 217 to penetrate the first electrode 212 and the first substrate 200, and stray light 300′, emitted from the non-pixel area due to current leakage is simultaneously blocked, avoiding light leakage and improving display performance.

Furthermore, by forming the light-shielding pattern 207 together with the source electrode 251/drain electrode 221 or the gate electrode 250 without significant additional fabricating steps or manufacturing costs.

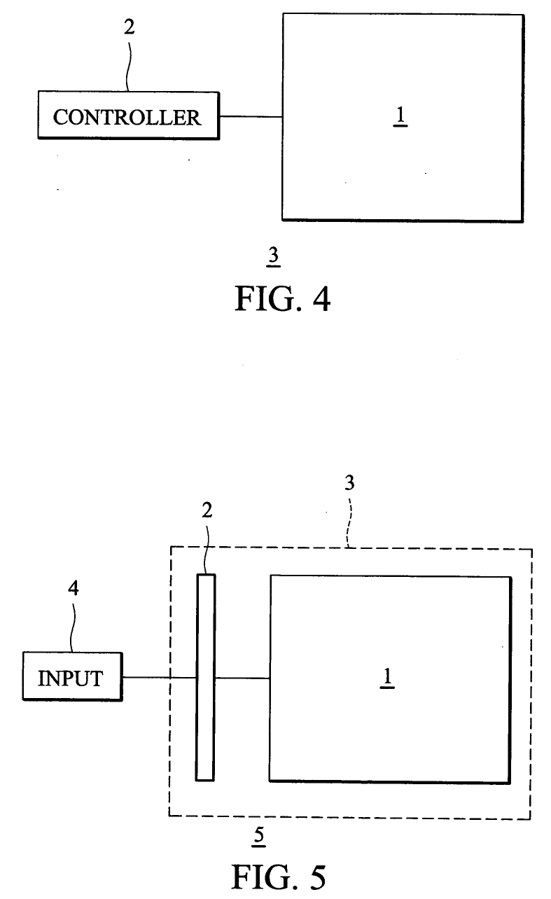

The organic light emitting device 1 of the present invention can be coupled to a controller 2 to form an organic light emitting display device 3. For example, the OLED display 1 shown in FIG. 4 can be coupled to a controller 2, forming an OLED display device 3. The controller 2 can comprise a source and gate driving circuits (not shown) to control the organic light emitting device 1 to render image in accordance with an input.

FIG. 5 is a schematic diagram illustrating an electronic device 5 incorporating the OLED display device 3 shown in FIG. 4. An input device 4 is coupled to the controller 2 of the OLED display device 3 to form an electronic device 5. The input device 4 can include a processor or the like to input data to the controller 2 to render an image. The electronic device 5 may be a portable device such as a PDA, notebook computer, tablet computer, cellular phone, or a display monitor device, or non-portable device such as a desktop computer.

The foregoing description has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

1. 1. An organic light-emitting device, comprising:
a substrate;
a first electrode supported by the substrate;
an organic light-emitting layer on the first electrode;
a second electrode on the organic light-emitting layer, wherein the first and second electrodes define a pixel area corresponding to an active light emitting area of the organic light-emitting layer; and
a light-shielding pattern defined outside the active light emitting area, to block stray light emitted by the organic light emitting-layer outside the active light emitting area.

2. The organic light-emitting device as claimed in claim 1, wherein the light-shielding pattern is an opaque pattern of metals, insulators or organic materials.

3. The organic light-emitting device as claimed in claim 1, wherein the organic light-emitting layer comprises small molecule or polymer organic light-emitting layer.

4. The organic light-emitting device as claimed in claim 1, Wherein the organic light-emitting layer comprising an electron-injecting layer, an electron-transport layer, a light-emitting layer, a hole-transport layer, and a hole-injecting layer.

5. The organic light-emitting device as claimed in claim 1, wherein the first electrode is an indium tin oxide (ITO) electrode.

6. The organic light-emitting device as claimed in claim 1, wherein the second electrode comprises Ca, Al, Mg, MgAg, AlLi, or a combination thereof.

7. The organic light-emitting device as claimed in claim 1, wherein the driving matrix comprises an amorphous-Si thin-film transistor or a poly-Si thin-film transistor.

8. The organic light-emitting device as claimed in claim 7, wherein the thin-film transistor comprises a gate electrode, and the light-shielding pattern is formed simultaneously with the gate electrode, by the same materials as the gate electrode.

9. The organic light-emitting device as claimed in claim 7, wherein the thin-film transistor comprises a source electrode and a drain electrode, and the light-shielding pattern is formed simultaneously with the source electrode and the drain electrode, by the same materials as the source electrode and the drain electrode.

10. The organic light-emitting device as claimed in claim 9, the light-shielding pattern is connected to the source electrode.

11. The organic light-emitting device as claimed in claim 1, further comprising a second substrate on the second electrode.

12. A display device, comprising:
a matrix of organic light emitting devices, each as in claim 1; and
a control circuit operatively coupled to control the matrix of organic light emitting devices.

13. An electronic device, comprising:
a display device as in claim 12;
an input for image data; and
a controller operatively coupled to the display device, controlling the display device to display an image in accordance with the image data.

14. A fabrication method for an organic light-emitting device, comprising:
providing a substrate;
forming a driving matrix on the substrate;
forming a light-shielding pattern on the substrate to define a plurality of pixel areas within the driving matrix;
forming a first electrode on the pixel area;
forming an organic light-emitting layer on the first electrode; and
forming a second electrode on the organic light-emitting layer.

15. The fabrication method as claimed in claim 14, wherein the driving matrix comprises an amorphous-Si thin-film transistor or a poly-Si thin-film transistor.

16. The fabrication method as claimed in claim 15, wherein the thin-film transistor comprises a gate electrode, and the light-shielding pattern is formed simultaneously with the gate electrode, by the same materials as the gate electrode.

17. The fabrication method as claimed in claim 15, wherein the thin-film transistor comprises a source electrode and a drain electrode, and the light-shielding pattern is formed simultaneously with the source electrode and the drain electrode, by the same materials as the source electrode and the drain electrode.
